(19) United States
(12) Patent Application Publication
(10) Pub. No.: US 2025/0246579 A1
(43) Pub. Date: Jul. 31, 2025

(54) INTEGRATED CIRCUIT (IC) DEVICE PACKAGING SYSTEM AND METHOD

(71) Applicant: TEXAS INSTRUMENTS INCORPORATED, DALLAS, TX (US)

(72) Inventors: DARYL KOEHL, GARLAND, TX (US); RAFFY MENDOZA, RICHARDSON, TX (US); WILLIAM MORRISON, PLANO, TX (US); BRADLEY HASKETT, MAGNOLIA, TX (US)

(21) Appl. No.: 18/731,599

(22) Filed: Jun. 3, 2024

Related U.S. Application Data
(60) Provisional application No. 63/625,149, filed on Jan. 25, 2024.

(51) Int. Cl. H01L 23/00; H01L 23/31; H01L 25/00

(52) U.S. Cl. CPC H01L 24/97; H01L 23/315; H01L 24/48; H01L 25/50; H01L 2224/48225; H01L 2224/97; H01L 2924/14; H01L 2924/15153

(57) ABSTRACT

One example method includes fabricating integrated circuit (IC) devices. The method includes obtaining an IC device panel. The IC device panel can include a substrate sheet and IC die. The substrate sheet can have a plurality of recesses each including inner sidewalls. Each of the IC die can be in one of the recesses of the substrate sheet. The method also includes cutting the IC panel along cut lines to singulate the IC devices. Each of the IC devices can include one of the IC die and a substrate formed from a portion of the substrate sheet. At least one of the cut lines can be through at least one of the recesses parallel with a peripheral edge of one of the IC die.

### CROSS-REFERENCE TO RELATED APPLICATION

This application claims priority to U.S. provisional patent application No. 63/625,149, filed Jan. 25, 2024, which is incorporated herein by reference in its entirety.

### TECHNICAL FIELD

This description relates to electronic circuits, and more specifically to an IC device packaging system and method.

### BACKGROUND

Integrated circuits (ICs) are typically fabricated in bulk as IC die on a semiconductor wafer. The IC die are singulated and attached to substrates via a die attach process. The die attach process can include, for example, attaching the IC die to a substrate sheet, such that additional electrical interconnects can also be provided between the IC die and the substrate sheet for a variety of different types of IC packages. The substrate sheet can thus be singulated to provide respective IC devices that can be packaged to form the IC circuit packages (e.g., IC chips). Certain environmental considerations can dictate particular geometries of the IC devices. Such environmental considerations can also conflict with the goal of decreasing the size of the IC packages.

### SUMMARY

One example method includes fabricating integrated circuit (IC) devices. The method includes obtaining an IC device panel. The IC device panel can include a substrate sheet and IC die. The substrate sheet can have a plurality of recesses each including inner sidewalls. Each of the IC die can be in one of the recesses of the substrate sheet. The method also includes cutting the IC panel along cut lines to singulate the IC devices. Each of the IC devices can include one of the IC die and a substrate formed from a portion of the substrate sheet. At least one of the cut lines can be through at least one of the recesses parallel with a peripheral edge of one of the IC die.

Another example includes an IC device. The device includes an IC die having a first peripheral edge and a second peripheral edge. The device also includes a substrate having a first outer surface, a second outer surface, and a recessed portion. The recessed portion can have a recessed surface and an inner surface. The IC die is on the recessed surface of the substrate, the first inner surface of the recessed portion is between the first peripheral edge of the IC die and the first outer surface of the substrate, and the second peripheral edge of the IC die is exposed to the second outer surface of the substrate.

Another example includes an IC package. The package includes an IC device. The device includes an IC die having a first peripheral edge, a second peripheral edge, and conductive bond pads. The device includes a substrate having a first outer surface, a second outer surface, a recessed portion, and electrical traces on a top surface. The recessed portion can have a recessed surface and an inner surface. The IC die is on the recessed surface of the substrate, the first inner surface of the recessed portion is between the first peripheral edge of the IC die and the first outer surface of the substrate, and the second peripheral edge of the IC die is exposed to the second outer surface of the substrate. The device also includes at least one set of electrical interconnects coupling the conductive bond pads of the IC die and the electrical traces of the substrate, the at least one set of electrical interconnects over the inner sidewall and the first peripheral edge of the IC die. The package also includes a cover layer over a second surface of the IC die opposite the first surface of the IC die and a molding material over the at least one set of electrical interconnects.

### BRIEF DESCRIPTION OF THE DRAWINGS

FIG. 1 is an example block diagram of an integrated circuit (IC) fabrication system.

FIGS. 2A and 2B are example diagrams of a recessed substrate sheet.

FIGS. 3A, 3B, and 3C are example diagrams of an IC panel.

FIG. 4 is an example diagram of singulation of IC devices from the IC panel.

FIG. 5 is another example diagram of singulation of IC devices from the IC panel.

FIGS. 6A, 6B, 6C, and 6D are example diagrams of an IC device.

FIG. 7 is another example diagram of an IC device.

FIGS. 8A, 8B, and 8C are example diagrams of an IC package.

FIG. 9 is an example of a method for fabricating IC devices.

### DETAILED DESCRIPTION

This description relates to electronic circuits, and more specifically to an integrated circuit (IC) device packaging system and method. An IC fabrication system can include fabrication equipment that is configured to fabricate a plurality of IC die and a recessed substrate sheet. The IC die can be fabricated on a semiconductor wafer, for example, and can be singulated into individual IC die. The recessed substrate sheet can include a plurality of recesses that each include a recessed surface relative to a top surface of the recessed substrate sheet, with each recessed surface being surrounded by inner sidewalls. For example, the resultant IC devices can be fabricated in resultant recessed substrates for a variety of reasons, such as environmental operating considerations. The recessed substrate sheet can be formed from a dielectric substrate material in any of a variety of ways to provide the recesses. As an example, the recessed substrate sheet can be formed from a layered ceramic material that is laminated and co-fired, from an injection molding process, or from an etching process on a silicon slab.

The IC fabrication system also includes die attach equipment that is configured to insert each of the IC die in a respective one of the recesses of the recessed substrate sheet. As an example, the IC die can be adhered via an adhesive material to the recessed surface. The recesses can be fabricated in the recessed substrate sheet to have dimensions that are suitable for receiving the IC die over a range of fabrication tolerances of the dimensions of the respective IC die. Therefore, there is a gap provided between the peripheral edges of each of the IC die and the opposing inner sidewalls of each of the respective recesses. As an example, the die attach equipment can also include equipment that can bond electrical interconnects between bond pads on the IC die and electrical traces on the recessed substrate sheet. For example, the recessed substrate sheet can be fabricated to include electrical traces and/or vias that can define electrical connections of the resultant IC package (e.g., pins or pads) to which the respective IC die are electrically connected. The electrical interconnects can thus be provided over at least one of the gaps defined by a respective at least one of the peripheral edges of each of the respective IC die and a respective at least one of the opposing inner sidewalls.

The IC fabrication system can further include a singulation tool that is configured to singulate the IC devices, such that each of the IC devices includes one of the IC die and a respective portion of the recessed substrate sheet. The IC die of each of the IC devices can thus be provided in a recessed portion of the substrate corresponding to a respective one of the recesses of the recessed substrate sheet. As an example, the singulation tool can be configured to provide mechanical singulation (e.g., via a saw), laser singulation (e.g., via a cutting laser), water cutting (e.g., via a water jet), or another manner of singulation (e.g., scribe-and-break singulation). The singulation tool is configured to provide at least one cut line that extends along a respective at least one of the gaps formed between a peripheral edge of the IC die and a respective opposing inner surface of the recess. As a result, a respective at least one of the peripheral edges of the IC die is completely exposed from the recess. Accordingly, the IC device described herein can be implemented for use in environments that can benefit from the recessed substrate, but can be provided in a smaller package than typical IC devices that include recessed substrates.

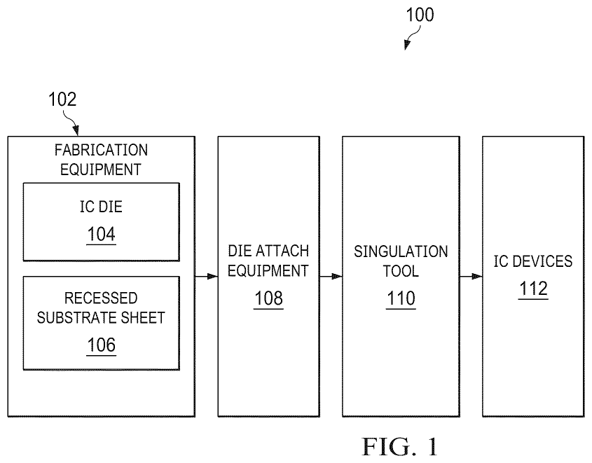

FIG. 1 is an example block diagram of an integrated circuit (IC) fabrication system 100. The IC fabrication system 100 can be implemented to fabricate any of a variety of IC devices that can operate for a variety of purposes. As described herein, the IC devices can be implemented in a sensitive environment, such as being subject to certain environmental considerations. Examples of such environments include extreme temperatures, extreme mechanical forces, or a variety of other considerations that may require design modifications relative to other conventional IC devices. For example, the IC devices can be implemented in one or more electrical systems in a vehicle. As described herein, one such design consideration is providing an IC die in a recessed substrate. The term “recessed substrate” refers herein to a substrate that includes a recessed surface relative to a top surface, with the recessed surface being at least partially surrounded by at least one inner sidewall.

The IC fabrication system 100 includes fabrication equipment 102 that is configured to fabricate a plurality of IC die 104 and a recessed substrate sheet 106. As described herein, the term “fabrication equipment”, including the fabrication equipment 102, can include multiple separate and distinct machines and fabrication processes, and are not limited to be collocated. The IC die 104 can be collectively fabricated on a semiconductor wafer, for example, and can be singulated into individual IC die 104. As described in greater detail herein, each of the IC die 104 can be fabricated to include conductive bond pads on an exterior surface to provide electrical connectivity to exterior components (e.g., conductive traces of the resultant substrates and/or pins or pads of the respective IC package). The recessed substrate sheet 106 can include a plurality of recesses that each include a recessed surface relative to a top surface of the recessed substrate sheet, with each recessed surface being surrounded by inner sidewalls. The recessed substrate sheet 106 can be formed from a dielectric substrate material in any of a variety of ways to provide the recesses. As an example, the recessed substrate sheet 106 can be formed from a layered ceramic material that is laminated and co-fired, from an injection molding process, or from an etching process on a silicon slab.

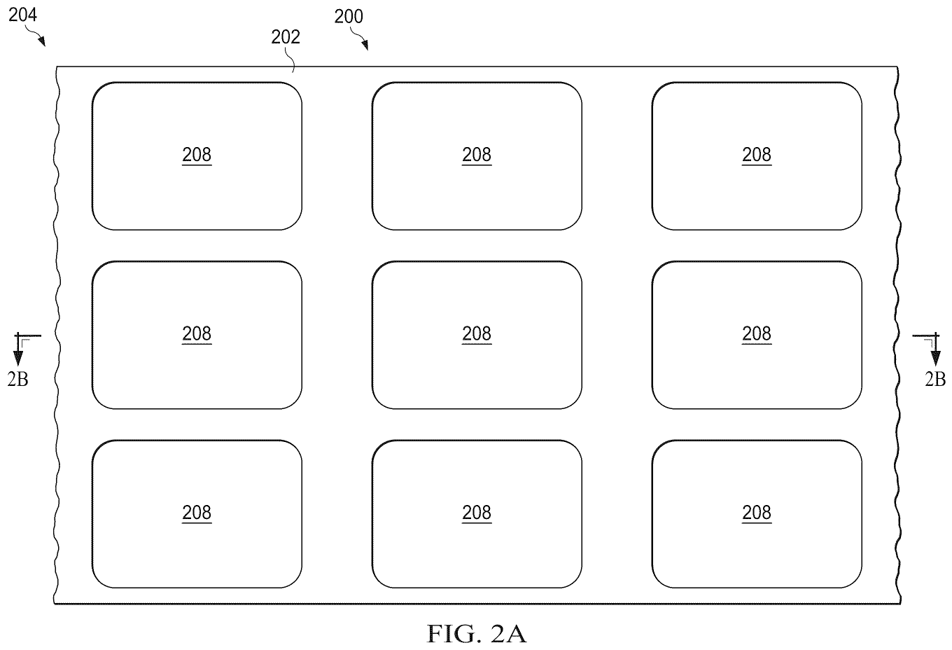

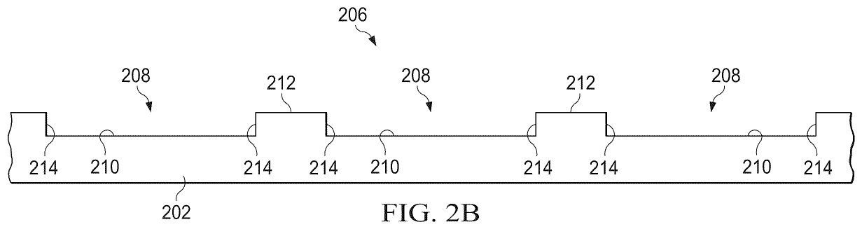

FIGS. 2A and 2B are example diagrams 200 of a recessed substrate sheet 202. The recessed substrate sheet 202 is demonstrated in the example of FIG. 2A corresponding to a plan view 204 and in the example of FIG. 2B corresponding to a cross-sectional view 206 taken along “2B”. The recessed substrate sheet 202 can correspond to the recessed substrate sheet 106 in the example of FIG. 1. Therefore, reference is to be made to the example of FIG. 1 in the following description of the example of FIG. 2.

The recessed substrate sheet 202 includes a plurality of recesses 208. Each of the recesses 208 includes a recessed surface 210 that is recessed relative to a top surface 212 of the recessed substrate sheet 202 and which is bounded or surrounded by inner sidewalls 214. The inner sidewalls 214 extend from the recessed surface 210 to the top surface 212 along each orthogonal edge of the recessed surface 210. In addition, the recessed substrate sheet 202 may require a portion of the dielectric material having the top surface 212 between recesses 208, particularly having a minimum distance. As an example, the fabricated recessed substrate sheet 202 may have approximately a minimum distance of additional dielectric material between the recesses 208 to maintain stability and structural integrity, particularly with respect to being handled by the fabrication equipment 102 and/or other handling equipment or devices (e.g., die attach equipment). Thus, the methodology of singulation described herein can provide for small IC packages while maintaining stability of the fabricated recessed substrate sheet 202.

The recessed substrate sheet 202 can be formed from a variety of different fabrication methods. As an example, the recessed substrate sheet 202 can be formed from a high-temperature co-fired ceramic (HTCC). In this example, the recessed substrate sheet 202 can be built from a stack of thin layers of ceramic material, which can then be laminated and co-fired. In this example, the recesses 208 can be formed by punching holes in the at least one layer of ceramic. Other example fabrication processes can be implemented. As another example, the recessed substrate sheet 202 can be formed from an injection molding process, such that the recesses 208 can be formed in preform. As yet another example, the recessed substrate sheet 202 can be formed from a slab of silicon, silicon dioxide, or other substrate material that can be etched (e.g., chemically, mechanically, or with an ablation laser) to form the recesses 208.

The recessed substrate sheet 202 is demonstrated in the example of FIG. 2 as one example. The recessed substrate sheet 202 can include more or fewer recesses 208 than the nine that are depicted in the example of FIG. 2. Additionally, part of the fabrication process of the fabrication equipment 102 in fabricating the recessed substrate sheet 202 can include forming electrically conductive vias and/or conductive traces in the recessed substrate sheet 202 that are not shown in the example of FIG. 2. The conductive vias and/or traces can be implemented to electrically connect the IC die 104 to conductive pins or pads of the resultant IC package for electrically connecting the IC package to a printed circuit board (PCB).

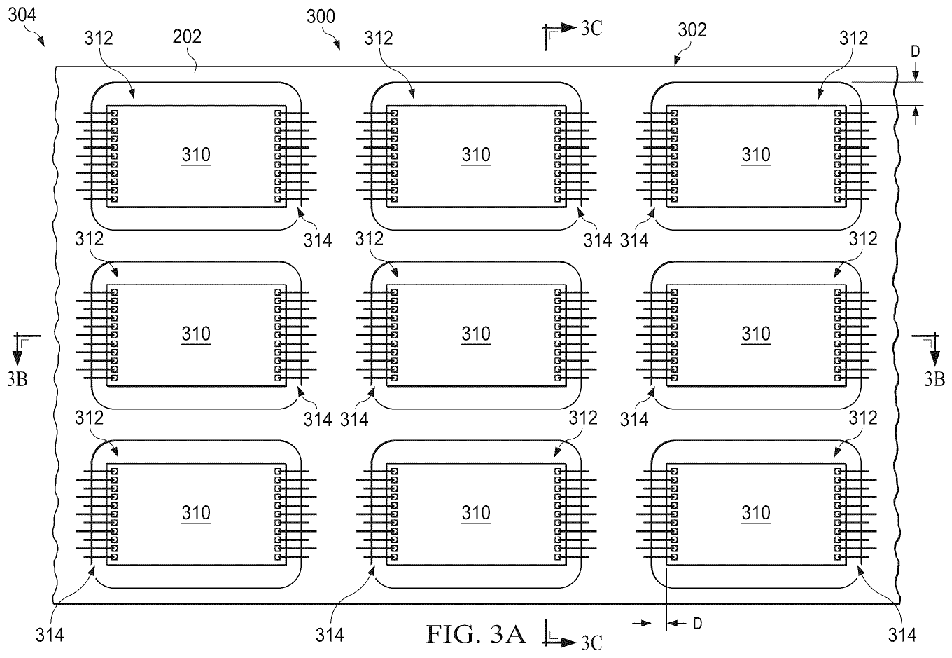

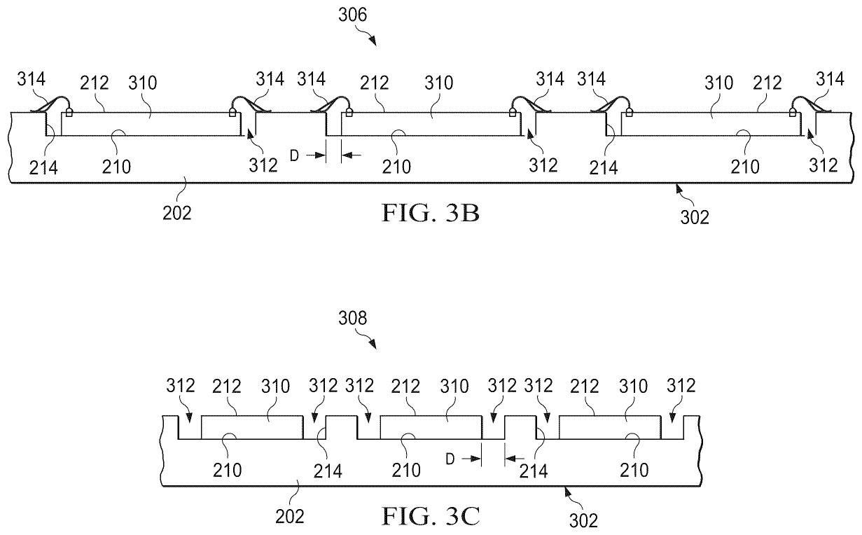

Referring back to the example of FIG. 1, the IC die 104 and the recessed substrate sheet 106 are provided to die attach equipment 108. The term “die attach equipment” refers to any of a collective variety of different devices, equipment, and/or processes that can attach the IC die 104 to the recessed substrate sheet 106, as well as adding additional processing layers or components, to form IC devices. The die attach equipment 108 is configured to insert the IC die 104 into the respective recesses of the recessed substrate sheet 106. Thus, each of the recesses 208 of the recessed substrate sheet 202 can be arranged to receive a respective one of the IC die 104. As an example, the die attach equipment 108 can be configured to provide an adhesive bond between a bottom surface of each of the IC die 104 to the recessed surface 210 of a respective one of the recesses 208. Based on fabrication tolerance variations, the dimensions of the recesses 208 (e.g., the linear distances between each opposing pair of the inner sidewalls 214 of each recess 208) can be greater than the dimensions of the respective IC die (e.g., the linear distances between each opposing pair of peripheral edges of the IC die 104). Therefore, inserting each of the IC die 104 into a respective one of the recesses 208 forms a gap between each of the inner sidewalls 214 and a respective opposing peripheral edge of the respective one of the IC die 104 (illustrated in FIG. 3).

The addition of the IC die 104 to the recessed substrate sheet 106 can thus form an IC panel that includes one of the IC die 104 in each of the recesses 208 of the recessed substrate sheet 202. The die attach equipment 108 can also be configured to provide additional fabrication steps. For example, the die attach equipment 108 can also include equipment/processes for electrically coupling electrical interconnects between the conductive bond pads on the IC die 104 to the electrical traces of the recessed substrate sheet 106. Therefore, the electrical interconnects can provide electrical connectivity from the IC die 104 to an exterior of the resultant IC package to form the inputs/outputs (I/O) of the resultant IC package. Furthermore, the die attach equipment 108 can provide additional operational components or layers, as well as a molding or potting material to cover at least a portion of each of the IC devices that include the respective IC die 104. Therefore, the die attach equipment 108 provides the IC panel that is ready to be singulated by a singulation tool 110.

FIGS. 3A, 3B, and 3C are example diagrams 300 of an IC panel 302. The IC panel 302 can correspond to the combined IC die 104 and the recessed substrate sheet 106, as provided by the die attach equipment 108. Therefore, reference is to be provided to the examples of FIGS. 1 and 2 in the following description of the example of FIG. 3.

The IC panel 302 is demonstrated in the example of FIG. 3A corresponding to a plan view 304, in the example of FIG. 3B corresponding to a cross-sectional view 306 taken along “3B”, and in the example of FIG. 3C corresponding to a cross-sectional view 308 taken along “3C”. The IC panel 302 includes the recessed substrate sheet 202 of the example of FIG. 2, including the recesses 208 and the top surface 212, as well as the recessed surfaces 210 and the inner sidewalls 214 of each of the recesses 208. The IC panel 302 also includes a plurality of IC die 310 that are each inserted into a respective one of the recesses 208. As an example, the IC die 310 can have been inserted into the recesses 208 of the recessed substrate sheet 202 via the die attach equipment 108, such as based on adhering the IC die 310 to the recessed surfaces 210 of the respective recesses 208.

Based on fabrication tolerance variations, the dimensions of the recesses 208 (e.g., the linear distances between each opposing pair of the inner sidewalls 214 of each recess 208) can be greater than the dimensions of the respective IC die (e.g., the linear distances between each opposing pair of peripheral edges of the IC die 104). Therefore, inserting each of the IC die 104 into a respective one of the recesses 208 forms a gap 312 between each of the inner sidewalls 214 and a respective opposing peripheral edge of the respective one of the IC die 104. In the example of FIG. 3, the gap 312 surrounds the recessed surface 210, and thus surrounds each of the IC die 310 disposed in the respective recess 208.

The dimensions between the inner sidewalls 214 and the peripheral edges of the IC die 104 is demonstrated as “D” in the example of FIG. 3, where D can be a distance that is sufficiently large to allow singulation via the singulation tool 110 without disturbing the inner sidewalls 214 and the peripheral edges of the IC die 104, and that is sufficiently small to conserve dielectric material and maintain a slim form-factor of the resultant IC device. As one example, the distance D can be approximately 0.65 mm, such that a cutting device (e.g., sawblade) of the singulation tool 110 having a width of approximately 300 μm has sufficient space on either side to accommodate fabrication tolerances to cut along the gap 312 without damaging the IC die 104 or the inner sidewalls 214. However, other values for the distance D can be implemented to accommodate fabrication tolerances in view of other tools or cutting techniques of the singulation tool 110.

As described above, the recessed substrate sheet 202 can be fabricated to include electrical traces (not shown) that extend along a surface of the recessed substrate sheet 202, such as the top surface 212 and/or the bottom surface 210 of the recessed substrate sheet 202 opposite the top surface 212, and/or can include electrical vias (not shown) that can extend between top surface 212 and the bottom surface 210. As also described above, the IC die 310 can each include conductive bond pads (not shown) on a top surface of the respective IC die 310 opposite the bottom surface that is adhered to the recessed surface 210 of the respective recess 208. In the example of FIG. 3, the IC die 310 are electrically coupled (e.g., via the conductive bond pads) to the top surface 212 of the recessed substrate sheet 202 (e.g., via the electrical traces and/or vias) by sets of electrical interconnects 314 that extend over the gaps 312 on opposing peripheral edges of the IC die 310. As an example, the electrical interconnects 314 can be configured as conductive wires (e.g., gold), or can be configured as conductive tabs, such as in the example of the top surface of the IC die 310 being approximately level with the top surface 212. For example, the electrical interconnects 314 can correspond to bond wires that can be conductively coupled to the conductive bond pads of the IC die 310 and the electrical traces and/or vias of the recessed substrate sheet 202 via any of a variety of conductive bonding techniques (e.g., solder).

The example of FIG. 3 demonstrates that each IC die 310 includes two sets of electrical interconnects 314 extending over gaps 312 defined by a peripheral edge of the respective IC die 310 and a respective inner sidewall 214 on opposite sides of the IC die 310. Therefore, the other (remaining) gaps 312 defined by a peripheral edge of the respective IC die 310 and a respective inner sidewall 214 on opposite sides of the IC die 310 does not include a set of electrical interconnects 314 extending thereover. However, other arrangements of electrical interconnects 314 are possible, such as a single set associated with each IC die 310 over a respective single gap 312, three sets associated with each IC die 310 over three respective gaps 312, or a non-oppositely arranged pair (e.g., with respect to gaps about the IC die 310) of the electrical interconnects 314 for each IC die 310. Additionally, the IC panel 302 can be arranged in a variety of other ways. For example, each of the recesses 208 can be formed large enough in the recessed substrate sheet 202 to accommodate two or more IC die 310, such as to reduce the amount of substrate material that is required to form the recessed substrate sheet 202.

Referring back to the example of FIG. 1, the singulation tool 110 is configured to singulate IC devices 112 from the IC panel that is formed by the recessed substrate sheet 106 and the IC die 104 (e.g., the IC panel 302). Therefore, each of the IC devices 112 includes one of the IC die 104 and a respective portion of the recessed substrate sheet 106. The IC die 104 of each of the IC devices 112 can thus be provided in a recessed portion of the substrate corresponding to a respective one of the recesses 208 of the recessed substrate sheet 202. As an example, the singulation tool can be configured to provide any of variety of ways to singulate the IC devices 112, such as mechanical singulation (e.g., via a saw), laser singulation (e.g., via a laser), or scribe-and-break singulation.

To provide the singulation, the singulation tool 110 is configured to provide at least one cut line that extends along the gaps 312 formed between peripheral edges of the IC die 310 and respective opposing inner sidewalls 214 of the recess 208. As a result, a respective at least one of the peripheral edges of the IC die is laterally exposed from the recessed portion of the substrate. Accordingly, the IC device 112 can be implemented for use in environments that can benefit from the recessed substrate portion, but can be provided in a smaller package than typical IC devices that include recessed substrates.

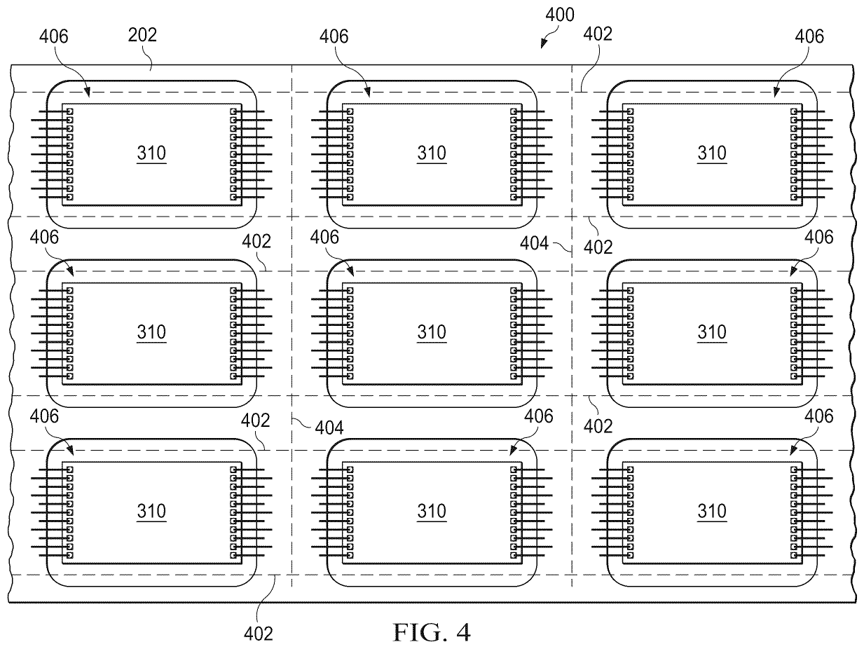

FIG. 4 is an example diagram 400 of singulation of IC devices from the IC panel 302. The IC panel 302 is demonstrated as was provided in the example of FIG. 3. However, the diagram 400 includes a first set of cut lines 402 that extend in a longitudinal direction along a length of the IC panel 302 and a second set of cut lines 404 that extend orthogonally with respect to the first set of cut lines 402 along a width of the IC panel 302. The cut lines 402 and 404 thus correspond to the linear cuts that are provided by the singulation tool 110 to singulate the IC devices 112 from the IC panel 302. In the example of FIG. 4, the first set of cut lines 402 are provided along the gaps 312 over which there are no extending electrical interconnects 314, as demonstrated at 406. Therefore, the first set of cut lines 402 are provided along the space between the peripheral edges of the IC die 310 and the respective opposing inner sidewall 214. For singulation of a given one of the IC devices 112, as demonstrated in the example of FIG. 4, the singulation tool 110 provides a pair of cut lines along two parallel gaps 312 associated with opposing peripheral edges of the respective IC die 310.

In the example of FIG. 4, instead of providing a single cut line between the horizontal rows of the IC die 310, the singulation tool 110 provides a pair of the first cut lines 402 between each row of the IC die 310, thereby removing any portion of the recessed substrate sheet 202 having the top surface 212 from between the rows of the IC die 310. As a result, each of the resultant IC devices can have a slimmer form factor relative to resultant IC devices from which the single horizontal cut line is provided. Furthermore, the singulation process can potentially be provided faster and/or more efficiently based on cutting through less substrate material by cutting along the gaps 312.

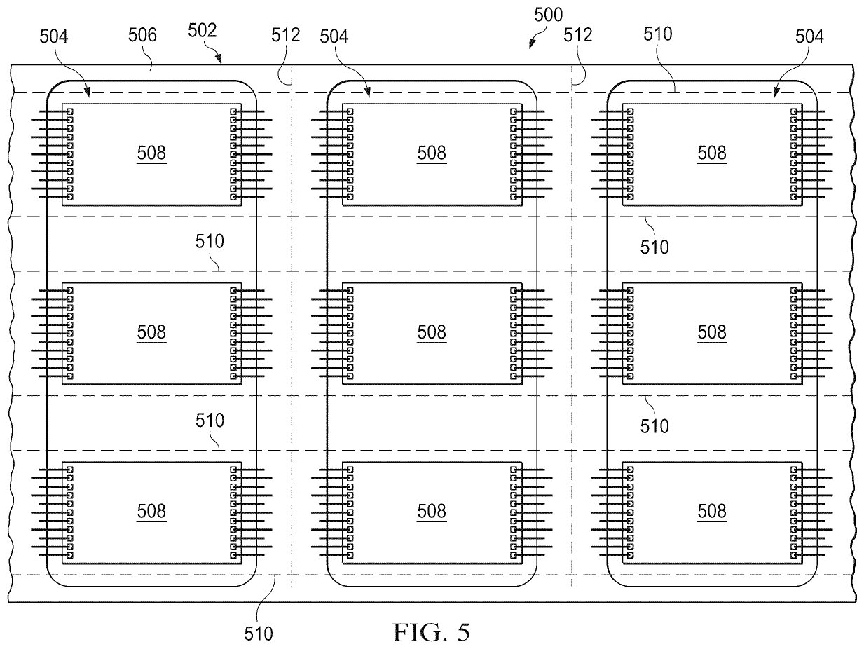

As described above, the IC panel 302 can be arranged in a variety of other ways that are not demonstrated in the examples of FIGS. 3 and 4. One example is demonstrated in the example of FIG. 5. FIG. 5 demonstrates another example diagram 500 of singulation of IC devices from an IC panel 502. In the example of FIG. 5, the IC panel 502 includes recesses 504 that can be formed large enough in a respective recessed substrate sheet 506 to accommodate two or more IC die 508. Singulation of individual IC devices in this example can thus result in length-wise cut lines 510 through each of the respective recesses 504 between adjacent IC die 508, as well as cut width-wise cut lines 512. In the example of FIG. 5, the amount of substrate material that is wasted during the singulation process can be mitigated.

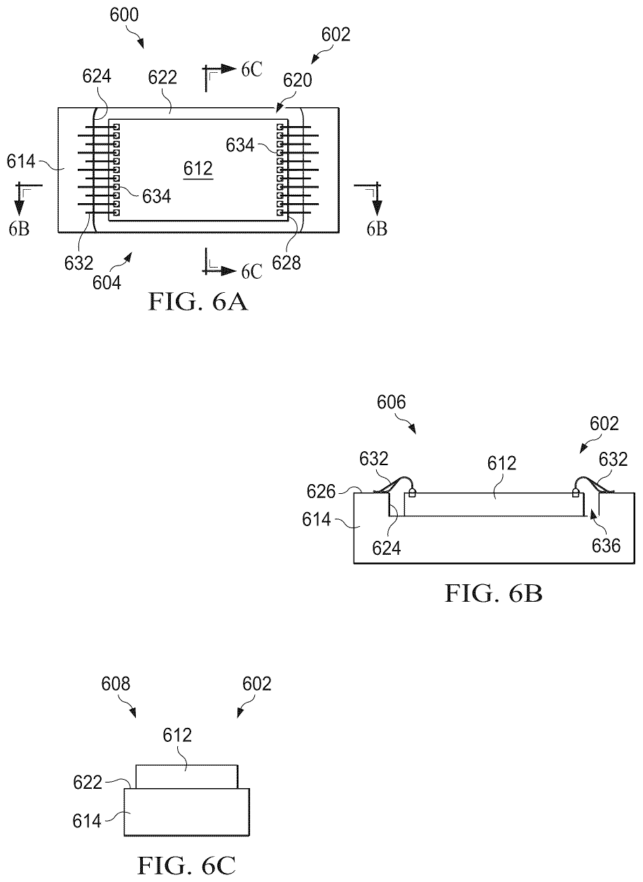

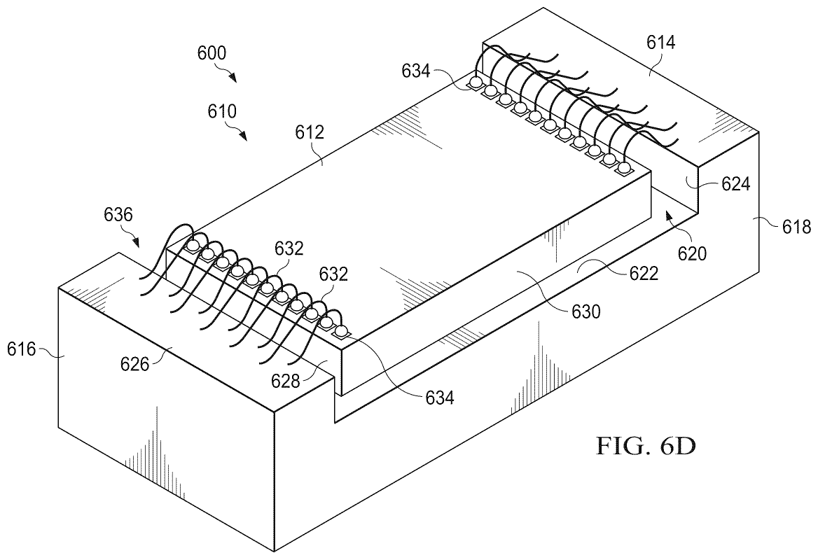

FIGS. 6A, 6B, and 6C are example diagrams 600 of an IC device 602. The IC device 602 is demonstrated in the example of FIG. 6A as a plan view 604 of the IC device 602, in the example of FIG. 6B as a cross-sectional view 606 of the IC device 602 taken along “6B”, in the example of FIG. 6C as a cross-sectional view 608 of the IC device 602 taken along “6C”, and in the example of FIG. 6D as perspective view 610. The IC device 602 includes an IC die 612 that can correspond to one of the IC die 310, and also includes a substrate 614 that can correspond to a portion of the recessed substrate sheet 202.

The substrate 614 includes a first outer surface 616, a second outer surface 618, and a recessed portion 620. The recessed portion 620 is demonstrated as having a recessed surface 622 and an inner surface 624. The IC die 612 is disposed on the recessed surface 622 of the substrate 614 relative to a top surface 626. The inner surface 624 of the recessed portion 620 is between a first peripheral edge 628 of the IC die 612 and the first outer surface 616 of the substrate 614. A second peripheral edge 630 of the IC die 612 is exposed to the second outer surface 618 of the substrate 614. In the example of FIG. 6, the IC die 612 has a pair of opposite first peripheral edges 628 and the substrate 614 has a respective opposing pair of inner surfaces 624. Further to the example of FIG. 6, a pair of opposite second peripheral edges 630 of the IC die 612 is exposed to a respective opposite pair of second outer surfaces 618 of the substrate 614.

The IC device 602 includes sets of electrical interconnects 632 that extend from conductive bond pads 634 across respective gaps 636 that are formed between respective peripheral edges 628 of the IC die 612 and inner surfaces 624 of the substrate 614 to the top surface 626 of the substrate 614. For example, the IC device 602 can be formed by singulating the IC panel 302 along the gaps 312 over which there are no electrical interconnects 314, as demonstrated in the example of FIG. 3. Therefore, the peripheral edges of the IC die 612 parallel to the cut lines 402 are not opposed by inner surfaces of the recessed substrate 614, and are therefore laterally exposed from the recessed substrate 614. The perspective view 610 demonstrates the laterally exposed second peripheral edge 630 of the IC die 612. As a result, the IC device 602 can have a slimmer form factor relative to conventional IC devices in a recessed substrate in which an IC die is disposed and completely surrounded by inner sidewalls. The IC device 602 can still, however, benefit from the recessed substrate 614 for use in implementations with certain environmental considerations.

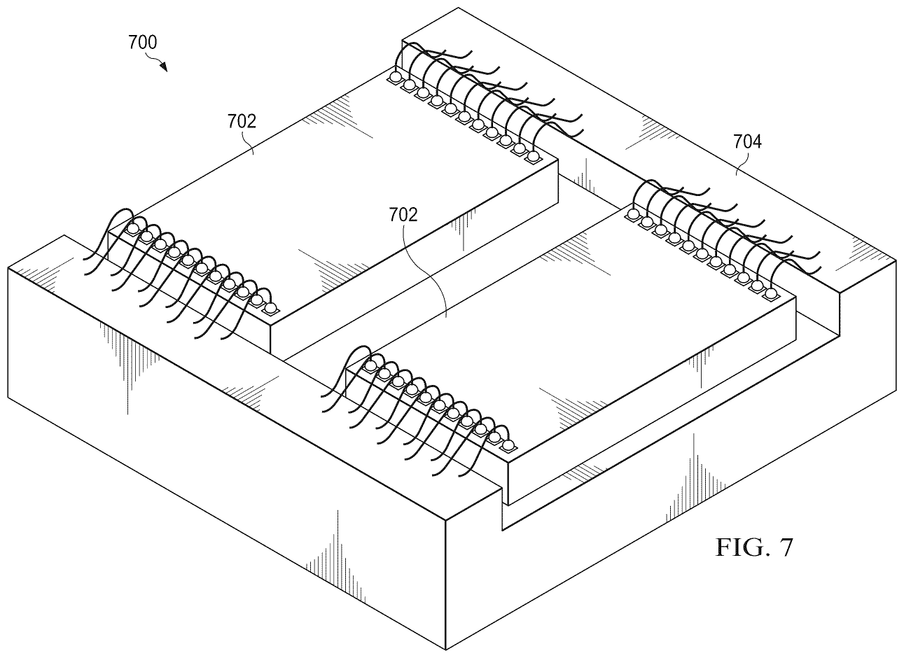

Other examples of IC devices are possible, as described herein. FIG. 7 is another example of an IC device 700, demonstrated in a perspective view. In the example of multiple IC die 508 provided in a single recess 504, as demonstrated in the example of FIG. 5, the cut lines 510 can still be provided along the gaps between the peripheral edges of the IC die 508 and the opposing inner sidewalls of the recesses 504. As a result, the singulated IC devices, such as the IC device 700, can include multiple IC die 702 on the same recessed substrate 704, such as to provide a multi-chip module (MCM).

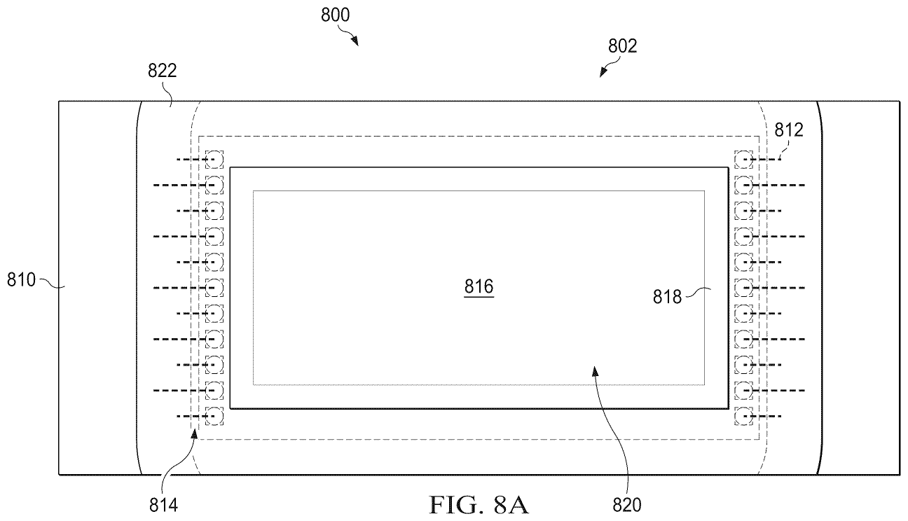

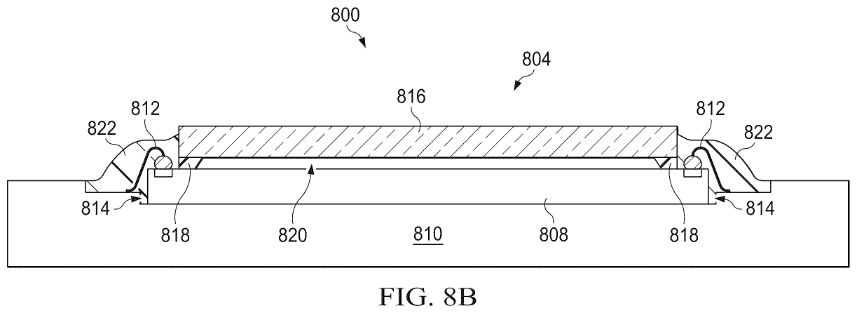

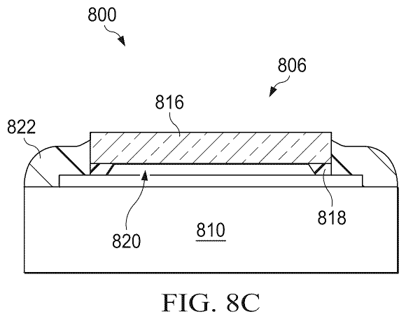

FIGS. 8A, 8B, and 8C are example diagrams of an IC package 800. The IC package is demonstrated in the example of FIG. 8A as a plan view 802, in the example of FIG. 8B corresponding to a cross-sectional view 804 taken along “8B”, and in the example of FIG. 8C corresponding to a cross-sectional view 806 taken along “8C”. The IC package 800 can correspond to an example of a resultant IC package of the IC device 602 after singulation of the IC device 602 from the IC panel 302. As described in the example of FIG. 8, the IC package 800 corresponds to a digital micromirror device (DMD). However, any of a variety of other types of IC devices/packages (e.g., an application specific integrated circuit (ASIC)) that can benefit from having a recessed substrate can be fabricated as described herein.

The IC package 800 includes an IC die 808 that may be an example of one of the IC die 612, and also includes a substrate 810 which may be an example of the substrate 614. In an example, the IC die 808 is a DMD die, and the substrate 810 is a ceramic substrate. In the example of FIG. 8, the substrate 810 is demonstrated as a recessed substrate, in that the IC die 808 is disposed on a recessed surface of the recessed substrate 810 relative to a top surface. The IC package 800 includes sets of electrical interconnects 812 that extend across respective gaps 814 that are formed between respective peripheral edges of the IC die 808 and inner surfaces of the recessed substrate 810. For example, the IC package 800 can be formed as an IC device by singulating the IC panel 302 along the gaps 312 over which there are no electrical interconnects 314, as demonstrated in the example of FIG. 3. Therefore, the peripheral edges of the IC die 808 parallel to the cut lines 402 are not opposed by inner surfaces of the recessed substrate 810, and are therefore laterally exposed from the recessed substrate 810 to allow for a slimmer form factor of the IC package 800 while still benefitting from the recessed substrate 810 for use in implementations with certain environmental considerations (e.g., temperature cycle testing for use in a broad range of temperatures).

In the example of FIG. 8, the IC package 800 also includes a cover 816 that is disposed on the IC die 808. As described above, the IC package 800 being implemented as a DMD, such that the IC die 808 can include an array of micromirrors having digitally-controlled positioning to generate an image (e.g., from an exterior light source). Therefore, in the example of the IC package being formed as a DMD, the cover 816 can be transparent (e.g., mostly optically transmissive, such as being formed of SiO₂ glass or any of a variety of other transparent materials). The cover 816 is disposed on seals 818 to form an air gap 820 between the cover 816 and the IC die 808 that is a sealed cavity. Furthermore, the IC package 800 includes a molding or potting material 822 that is formed over the electrical interconnects 812 (e.g., and into the gaps 814) to protect the electrical interconnects 812 from exterior contact. The fabrication of the IC package 800 can be such that differing coefficients of thermal expansion of the different materials of the substrate 810, the air gap 820, and the potting material 822 can be accommodated by the design of the IC package 800, thereby allowing operation of the IC package 800 in a broader range of temperatures, but in a more compact form-factor than conventional DMD circuits based on the fabrication techniques described herein.

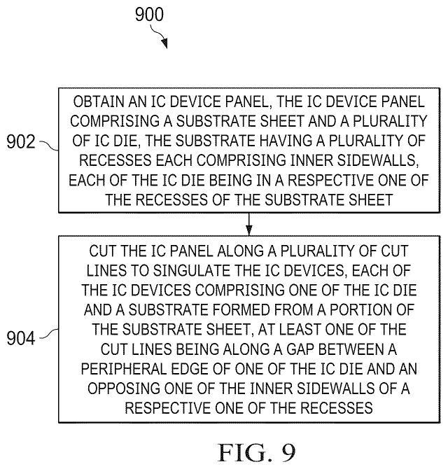

In view of the foregoing structural and functional features described above, methodologies in various aspects of the description will be better appreciated with reference to FIG. 9. The method of FIG. 9 is not limited by the illustrated order, as some aspects could, in the present description, occur in different orders and/or concurrently with other aspects from that shown and described herein. Moreover, not all illustrated features may be required to implement methodologies in an aspect of the present examples.

FIG. 9 is an example of a method 900 for fabricating a plurality of integrated circuit (IC) devices (e.g., the IC devices 112). At 902, an IC device panel (e.g., the IC panel 302) is obtained. The IC device panel can include a substrate sheet (e.g., the recessed substrate sheet 106) and a plurality of IC die (e.g., the IC die 104). The substrate sheet being formed from a dielectric substrate material and including a plurality of recesses (e.g., the recesses 208) each including inner sidewalls (e.g., the inner sidewalls 214). Each of the IC die can be inserted into one of the recesses of the substrate sheet. At 904, the IC panel is cut along a plurality of cut lines (e.g., the cut lines 402) to singulate the IC devices. Each of the IC devices can include one of the IC die and a substrate (e.g., the substrate 614) formed from a portion of the substrate sheet. At least one of the cut lines can be through at least one of the recesses parallel with a peripheral edge of one of the IC die.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistor devices), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A method for fabricating an integrated circuit (IC) device, the method comprising:
obtaining an IC device panel, the IC device panel comprising a substrate sheet and a plurality of IC die, the substrate sheet having a plurality of recesses each comprising inner sidewalls, each of the IC die being in one of the recesses of the substrate sheet; and
cutting the IC panel along a plurality of cut lines to singulate the IC devices to produce the IC device, the IC device comprising one of the IC die and a substrate formed from a portion of the substrate sheet, at least one of the cut lines being through at least one of the recesses of one of the IC die.

2. The method of claim 1, wherein each of the IC die are adhered to a recessed surface of the respective one of the recesses relative to a top surface of the substrate sheet, the recessed surface being surrounded by the inner sidewalls of the respective one of the recesses to provide a plurality of gaps between peripheral edges of a respective one of the IC die and the respective opposing inner sidewalls of the respective one of the recesses, the at least one of the cut lines being along at least one of the respective gaps between the peripheral edge of one of the IC die and an opposing one of the inner sidewalls of a respective one of the recesses.

3. The method of claim 2, wherein the substrate sheet comprises conductive traces on the top surface, wherein each of the IC die comprises conductive bond pads, wherein the IC device panel further comprises electrical interconnects extending between the conductive traces and the conductive bond pads over at least one of the gaps.

4. The method of claim 3, wherein the gaps comprise first gaps across which the electrical interconnects extend, and second gaps, wherein the at least one of the cut lines is along one of the second gaps.

5. The method of claim 4, wherein the electrical interconnects extend between the conductive traces and the conductive bond pads over two of the gaps associated with opposing peripheral edges of the respective IC die, wherein the at least one of the cut lines is along two other gaps associated with the other opposing peripheral edges of the respective IC die.

6. The method of claim 1, wherein each of the IC die are inserted into the respective one of the recesses relative to a top surface of the substrate sheet, such that there is a respective gap between each peripheral edge of each of the IC die and each respective inner sidewall of the respective one of the recesses.

7. The method of claim 6, wherein the IC panel has a pair of cut lines along two parallel gaps associated with opposing peripheral edges of the respective IC die.

8. The method of claim 1, wherein each of the recesses of the IC device panel has a plurality of IC die.

9. The method of claim 1, wherein each of the IC devices comprises a plurality of IC die to form a multi-chip module (MCM).

10. An integrated circuit (IC) device comprising:
an IC die having a first peripheral edge and a second peripheral edge; and
a substrate having a first outer surface, a second outer surface, and a recessed portion, the recessed portion having a recessed surface and an inner surface, wherein the IC die is on the recessed surface of the substrate, and wherein the inner surface of the recessed portion is between the first peripheral edge of the IC die and the first outer surface of the substrate, and wherein the second peripheral edge of the IC die is exposed to the second outer surface of the substrate.

11. The device of claim 10, wherein the substrate comprises conductive traces on a top surface, wherein the IC die comprises conductive bond pads, the device further comprising electrical interconnects electrically coupled between the conductive traces and the conductive bond pads and extending over at least one gap between the first peripheral edge of the IC die and the inner surface.

12. The device of claim 10, wherein the IC die comprises a plurality of first peripheral edges and the substrate comprises a plurality of inner surfaces, wherein a quantity of the first peripheral edges is equal to a quantity of the inner surfaces between which the electrical interconnects extend, such that a remaining at least one second peripheral edge of the IC die is exposed to a respective at least one second outer surface of the substrate.

13. The device of claim 10, wherein the IC die has a pair of opposite first peripheral edges and the substrate has a respective opposing pair of inner surfaces, wherein a pair of opposite second peripheral edges of the IC die is exposed to a respective opposite pair of second outer surfaces of the substrate.

14. The device of claim 10, wherein the second peripheral edge of the IC die that is exposed to the second outer surface of the substrate results from singulation of a plurality of IC devices via a singulation tool that is configured to cut a substrate sheet comprising a plurality of recesses with a cut line along a gap between the second peripheral edge and an opposing inner sidewall relative to the second peripheral edge.

15. The device of claim 10, wherein the IC die comprises a digital micromirror device.

16. The device of claim 10, wherein the IC device comprises a plurality of IC die to form a multi-chip module (MCM).

17. An integrated circuit (IC) device comprising:
an IC die having a first surface, a first peripheral edge, a second peripheral edge, and conductive bond pads;
a substrate having a first outer surface, a second outer surface, a recessed portion, and electrical traces on a top surface, the recessed portion having a recessed surface, an inner surface, wherein the IC die is on the recessed surface of the substrate, and wherein the inner surface of the recessed portion is between the first peripheral edge of the IC die and the first outer surface of the substrate, and wherein the second peripheral edge of the IC die is exposed to the second outer surface of the substrate; and
at least one set of electrical interconnects coupling the conductive bond pads of the IC die and the electrical traces of the substrate, the at least one set of electrical interconnects over an inner sidewall and the first peripheral edge of the IC die;
a cover layer over a second surface of the IC die opposite the first surface of the IC die; and
a molding material over the at least one set of electrical interconnects.

18. The device of claim 17, wherein the IC die comprises a pair of opposite first peripheral edges and the substrate comprises a respective opposing pair of inner surfaces, wherein a pair of opposite second peripheral edges of the IC die is exposed to a respective opposite pair of second outer surfaces of the substrate.

19. The device of claim 17, wherein the cover layer is transparent.

20. The device of claim 17, wherein the IC die is arranged as a digital micromirror device.
